(19) United States
(12) Patent Application Publication
(10) Pub. No.: US 2013/0319734 A1
(43) Pub. Date: Dec. 5, 2013

(54) PACKAGE SUBSTRATE AND METHOD OF MANUFACTURING THE SAME

(71) Applicants: Sang Hyun Shin, Gyunggi-do (KR); Kwang Jik Lee, Gyunggi-do (KR); Hye Sook Shin, Gyunggi-do (KR); Joon Seok Kang, Gyunggi-do (KR)

(72) Inventors: Sang Hyun Shin, Gyunggi-do (KR); Kwang Jik Lee, Gyunggi-do (KR); Hye Sook Shin, Gyunggi-do (KR); Joon Seok Kang, Gyunggi-do (KR)

(73) Assignee: SAMSUNG ELECTRO-MECHANICS CO., LTD., Gyunggi-do (KR)

(21) Appl. No.: 13/595,900

(22) Filed: Aug. 27, 2012

(30) Foreign Application Priority Data
May 31, 2012 (KR) 10-2012-0058497

(51) Int. Cl. H05K 1/11; H05K 3/42; H05K 1/03

(52) U.S. Cl. 174/255; 174/266; 427/97.8

(57) ABSTRACT

Disclosed herein is a package substrate including: a base substrate; insulation layers formed on upper and lower portions of the base substrate; a first metal layer formed on an upper portion of the insulation layer; a first through-via penetrating through the base substrate, the insulation layer, and the first metal layer and being made of an insulating material; a seed layer formed on upper and lower portions and an inner wall of the first through-via; a second metal layer formed on upper portions of the first metal layer and the seed layer; and a second through-via formed in the seed layer formed at the inner wall of the first through-via and the second metal layer.

### CROSS REFERENCE TO RELATED APPLICATION

This application claims the benefit of Korean Patent Application No. 10-2012-0058497, filed on May 31, 2012, entitled “Package Substrate and Method of Manufacturing the Same”, which is hereby incorporated by reference in its entirety into this application.

### BACKGROUND OF THE INVENTION

1. Technical Field

The present invention relates to a package substrate and a method of manufacturing the same.

2. Description of the Related Art

In accordance with the rapid development of a semiconductor technology, a semiconductor device has significantly grown. Further, the development for a semiconductor package such as a system in package (SIP), a chip sized package (CSP), a flip chip package (FCP), or the like, configured as a package by mounting an electronic device such as the semiconductor device on a printed circuit substrate in advance has been actively conducted. This semiconductor package requires capability to excellently radiate heat generated from the semiconductor device and insulation capability at a high voltage. In order to solve a heat radiation problem, an effort to manufacture various types of package substrates using a metal material having excellent heat conduction characteristics has been made. Recently, research into a package substrate for maximizing the heat radiation of the semiconductor device using anodizing has been conducted. In the package substrate according to the prior art, an anodized film is formed on a surface of an aluminum substrate in which a through-hole is formed. In this case, the anodized film is also formed on an inner wall of the through-hole (U.S. Pat. No. 7,947,906). After the anodized film is formed, the through-hole is filled by plating, or the like, thereby forming a through-via and other circuit patterns.

### SUMMARY OF THE INVENTION

The present invention has been made in an effort to provide a package substrate capable of preventing a crack from being generated in an insulation layer at the time of performing plating on a through-hole, and a method of manufacturing the same.

Further, the present invention has been made in an effort to provide a package substrate capable of preventing a crack from being generated in an insulation layer at the time of forming a through hole, and a method of manufacturing the same.

Further, the present invention has been made in an effort to provide a package substrate capable of preventing an insulation layer from being damaged due to a polishing process after a through-via is formed, and a method of manufacturing the same.

According to a preferred embodiment of the present invention, there is provided a package substrate including: a base substrate; insulation layers formed on upper and lower portions of the base substrate; a first metal layer formed on an upper portion of the insulation layer; a first through-via penetrating through the base substrate, the insulation layer, and the first metal layer and being made of an insulating material; a seed layer formed on upper and lower portions and an inner wall of the first through-via; a second metal layer formed on upper portions of the first metal layer and the seed layer; and a second through-via formed in the seed layer formed at the inner wall of the first through-via and the second metal layer.

The base substrate may be made of aluminum.

The insulation layer may be an anodized film.

The insulating material may be insulating plugging ink.

The seed layer may be formed by a wet method or a dry method.

The second through-via may be formed by at least one of plating, insulating plugging ink, and a conductive paste.

According to another preferred embodiment of the present invention, there is provided a method of manufacturing a package substrate, the method including: preparing a base substrate; forming insulation layers at upper and lower portions of the base substrate; forming a first metal layer at an upper portion of the insulation layer; forming a first through-hole penetrating through the base substrate, the insulation layer, and the first metal layer; filling an inner portion of the through-hole with an insulating material to form a first through-via; forming a second through-via penetrating through an inner portion of the first through-via; forming a seed layer at upper and lower portions and an inner wall of the second through-hole; forming a second metal layer at upper portions of the first metal layer and the seed layer; and filling an inner portion of the second through-hole with a conductive material to form a second through-via.

The base substrate may be made of aluminum.

In the forming of the insulation layers, the base substrate may be anodized.

In the forming of the first through-via, the insulating material may be insulating plugging ink.

In the forming of the seed layer, the seed layer may be formed by a wet method or a dry method.

The second through-via may be formed by at least one of plating, insulating plugging ink, and a conductive paste.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a package substrate according to a preferred embodiment of the present invention; and

FIGS. 2 to 10 are views showing a method of manufacturing a package substrate according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

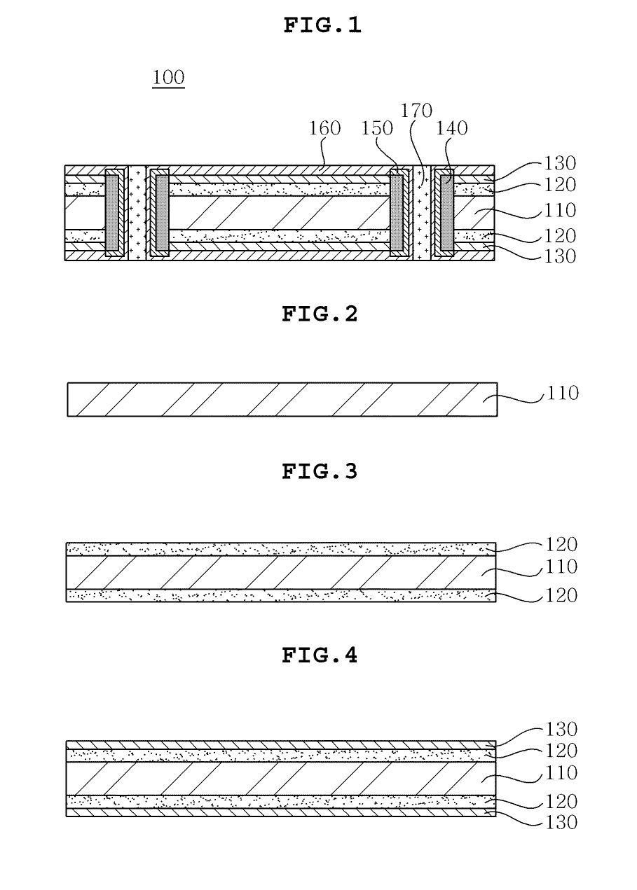

FIG. 1 is a view showing a package substrate according to a preferred embodiment of the present invention.

Referring to FIG. 1, the package substrate 100 may be configured to include a base substrate 110, an insulation layer 120, a first metal layer 130, a first through-via 140, a seed layer 150, a second metal layer 160, and a second through-via 170.

The base substrate 110 may be made of a metal. For example, the base substrate 110 may be made of aluminum (Al). However, a material of the base substrate 110 is not limited to aluminum. The base substrate 110 may be made of magnesium (Mg), zinc (Zn), titanium (Ti), hafnium (Hf), or the like, to which an anodizing method may be applied.

The insulation layers 120 may be formed on upper and lower portions of the base substrate 110. The insulation layer 120 may be an anodized film formed by anodizing the base substrate 110. In the case in which the base substrate 110 is made of aluminum, the insulation layer 120 formed by the anodizing may be an alumina layer. The first metal layer 130 may be formed on an upper portion of the insulation layer 120. The first metal layer 130 may be formed by an electroless plating or electroplating method. The first metal layer 130 may be made of a conductive metal. For example, the first metal layer 130 may be made of at least one material selected from a group consisting of nickel (Ni), titanium (Ti), copper (Cu), and chromium (Cr). The first metal layer 130 may serve as a buffer layer for reducing damage of the first insulation layer 120 at the time of forming a first through-hole 210.

The first through-via 140 may be formed to penetrate through the base substrate 110, the insulation layer 120, and the first metal layer 130. The first through-via 140 may be made of an insulating material. For example, the first through-via 140 may be made of insulating plugging ink. The upper and lower portions of the base substrate 110 may be electrically insulated from each other by the first through-via 140.

The seed layer 150 may be formed on upper and lower portions and an inner wall of the first through-via 140. The Seed layer 150 may be formed by a wet method or a dry method. For example, the Seed layer 150 may be formed by a dry method such as sputtering, e-beam, or the like. In addition, the Seed layer 150 may be formed by a wet method such as Electroless plating, or the like. Here, the seed layer 150 may be made of a conductive metal. For example, the seed layer 150 may be made of copper. However, a material of the seed layer 150 is not limited to copper. The seed layer 150 may be made of any conductive metal capable of performing the same function as that of copper.

The second metal layer 160 may be formed on upper portions of the first metal layer 130 and the seed layer 150. The second metal layer 160 may be formed by an electroplating method. Here, the second metal layer 160 may be made of a conductive metal. For example, the second metal layer 160 may be made of copper. However, a material of the second metal layer 160 is not limited to copper. The second metal layer 160 may be made of any conductive metal capable of performing the same function as that of copper.

The seed layer 150 and the second metal layer 160 are formed on the upper and lower portions and the inner wall of the first through-via 140, thereby making it possible to electrically connect the upper and lower portions of the base substrate 110 to each other.

The second through-via 170 may be formed in the first through-via 140. That is, the second through-via 170 may be formed in the seed layer 150 formed at the inner wall of the first through-via 140 and the second metal layer 160. The second through-via 170 may be formed by a conductive paste, insulating plugging ink, or plating. The second through-via 170 may be made of the conductive metal. For example, the second through-via 170 may be made of at least one material selected from a group consisting of silver (Ag), copper (Cu), and nickel (Ni).

With the package substrate 100 according to the preferred embodiment of the present invention, the seed layer 150 and the second metal layer 160 do not directly contact the insulation layer 120 due to the first through-via 140. Therefore, at the time of forming the seed layer 150 and the second metal layer 160, the plating is directly performed on the insulation layer 120, thereby making it possible to prevent a crack from being generated in the insulation layer 120.

FIGS. 2 to 10 are views showing a method of manufacturing a package substrate according to the preferred embodiment of the present invention.

Referring to FIG. 2, a base substrate 110 is provided. The base substrate 110 may be made of a metal. For example, the base substrate 110 may be made of aluminum (Al). However, a material of the base substrate 110 is not limited to aluminum. The base substrate 110 may be made of magnesium (Mg), zinc (Zn), titanium (Ti), hafnium (Hf), or the like, to which an anodizing method may be applied.

Referring to FIG. 3, insulation layers 120 may be formed on the base substrate 110. The insulation layers 120 may be formed on upper and lower portions of the base substrate 110. The insulation layer 120 may be formed by anodizing the base substrate 110. The anodizing, which means a process of conducting an object to be processed (for example, aluminum or an aluminum alloy) to an anode in an electrolyte such as sulfuric acid, oxalic acid, or the like, is a process of oxidizing a surface of the object to be processed to form an anodized film in a depth direction. More specifically, when it is assumed that the base substrate 110 is made of aluminum, the surface of the base substrate 110 reacts with the electrolyte, such that aluminum ions (Al3+) may be generated at a boundary surface. In addition, current density is concentrated on the surface of the base substrate 110 by voltage applied to the base substrate 110 to generate local heat, thereby making it possible to generate more aluminum ions. As a result, a plurality of grooves are formed in the surface of the base substrate 110, and oxygen ions (O2−) move to the grooves due to force of an electric field to react with the aluminum ions, thereby making it possible to forming an alumina layer. Here, since the alumina layer has higher thermal conductivity as compared to other insulating members, even though the alumina layer is formed over the entire surface of the aluminum, heat radiation of aluminum may be smoothly performed.

That is, in the case in which the base substrate 110 is made of aluminum, the insulation layer 120 formed by the anodizing may be the alumina layer.

Referring to FIG. 4, a first metal layer 130 may be formed on an upper portion of the insulation layer 120. The first metal layer 130 may be formed by an electroless plating or electroplating method. The first metal layer 130 may be made of a conductive metal. For example, the first metal layer 130 may be made of at least one material selected from a group consisting of nickel (Ni), titanium (Ti), copper (Cu), and chromium (Cr). The first metal layer 130 may serve as a buffer layer for reducing damage of the first insulation layer 120 at the time of forming a first through-hole 210 later.

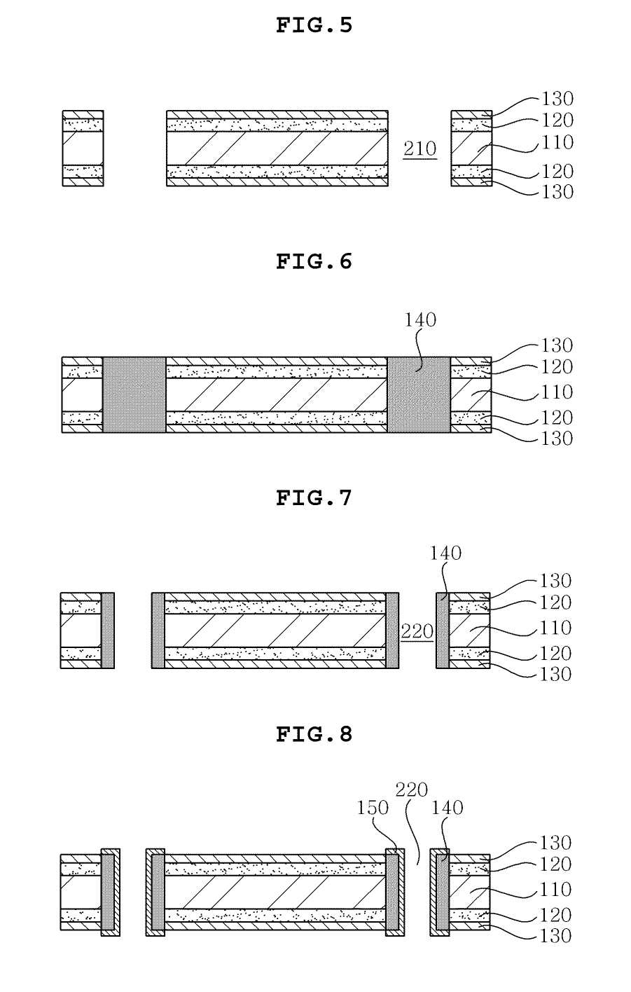

Referring to FIG. 5, a first through-hole 210 may be formed. The first through-hole 210 may be formed to penetrate through the base substrate 110, the insulation layer 120, and the first metal layer 130. The first through-hole 210 may be formed by mechanical drilling, laser drilling, or chemical etching. At the time of forming the first through-hole 210, generation of damage such as a crack of the first insulation layer 120, or the like, due to impact may be reduced by the first metal layer 130.

Referring to FIG. 6, a first through-via 140 may be formed. The first through-via 140 may be formed by filling an inner portion of the first through-hole 210 with an insulating material. For example, the first through-via 140 may be formed by filling the first through-hole 210 with insulating plugging ink. For example, a mask having a hole formed therein so that a portion corresponding to the first through-hole 210 is exposed is positioned so as to contact the first metal layer 130 and the plugging ink is then applied on an upper surface of the mask. Then, the plugging ink is pushed to the outside of the hole of the mask using a squeegee Therefore, the plugging ink may be filled in the first through-hole 210 while being discharged through the hole of the mask. After the plugging ink is filled in the first through-hole 210, a polishing process may be performed in order to planarize the surface. In this case, heights of the first through-via 140 made of the plugging ink and the first metal layer 130 become the same as each other, such that surfaces thereof may become flat. At the time of performing the polishing process as described above, damage of the first insulation layer 120 may be prevented by the first metal layer 130.

Referring to FIG. 7, an inner portion of the first through-via 140 may be formed with a second through-hole 220. The second through-hole 220 may be formed by a mechanical drill or a laser drill.

Referring to FIG. 8, a seed layer 150 may be formed on upper and lower portions and an inner wall of the second through-hole 220. The Seed layer 150 may be formed by a wet method or a dry method. For example, the Seed layer 150 may be formed by a dry method such as sputtering, e-beam, or the like. In addition, the Seed layer 150 may be formed by a wet method such as Electroless plating, or the like. Here, the seed layer 150 may be made of a conductive metal. For example, the seed layer 150 may be made of copper. However, a material of the seed layer 150 is not limited to copper. The seed layer 150 may be made of any conductive metal capable of performing the same function as that of copper.

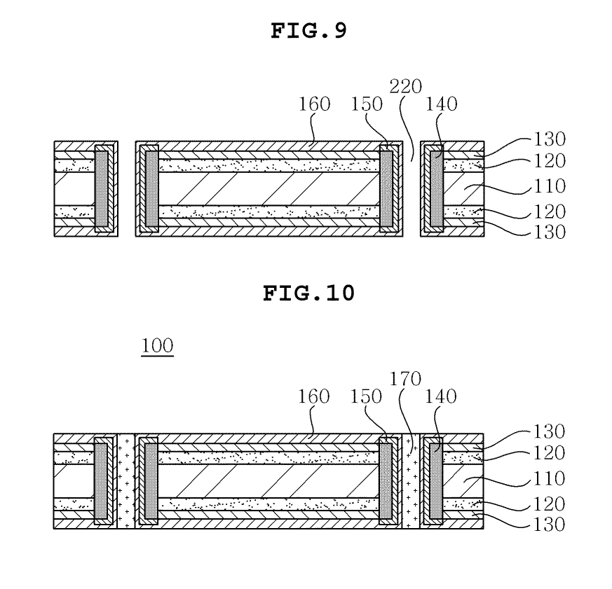

Referring to FIG. 9, a second metal layer 160 may be formed on upper portions of the first metal layer 130 and the seed layer 150. The second metal layer 160 may be formed by an electroplating method. Here, the second metal layer 160 may be made of a conductive metal. For example, the second metal layer 160 may be made of copper. However, a material of the second metal layer 160 is not limited to copper. The second metal layer 160 may be made of any conductive metal capable of performing the same function as that of copper.

The seed layer 150 and the second metal layer 160 according to the preferred embodiment of the present invention may be formed in order to electrically connect the upper and lower portions of the base substrate 110 to each other. That is, the upper and lower portions of the base substrate 110 may be electrically connected to each other by the seed layer 150 formed on the inner wall of the second through-hole 220 and the second metal layer 160.

Referring to FIG. 10, a second through-via 170 may be formed. The second through-via 170 may be formed by filling the second through-hole 220 with a conductive paste or insulating plugging ink or by the plating. A method of forming the second through-via 170 by the conductive paste, insulating plugging ink, or the plating may be performed by a technology generally known in the art. The second through-via 170 may be made of a conductive metal. For example, the second through-via 170 may be made of at least one material selected from a group consisting of silver (Ag), copper (Cu), and nickel (Ni). The package substrate 100 may be formed by the above-mentioned processes. With the method of manufacturing package substrate 100 according to the preferred embodiment of the present invention, the seed layer 150 and the second metal layer 160 do not directly contact the insulation layer 120 due to the first through-via 140. Therefore, at the time of forming the seed layer 150 and the second metal layer 160, the plating is directly performed on the insulation layer 120, thereby making it possible to prevent a crack from being generated in the insulation layer 120.

As set forth above, with the package substrate and the method of manufacturing the same according to the preferred embodiment of the present invention, after the insulation layer is formed, the first through-via is formed, thereby making it possible to prevent the crack from being generated in the insulation layer at the time of performing the plating for forming the second through-via.

In addition, with the package substrate and the method of manufacturing the same according to the preferred embodiment of the present invention, after the first metal layer is formed on the upper portion of the insulation layer, the through-hole is formed, thereby making it possible to prevent the crack from being generated in the insulation layer due to the formation of the through-hole.

Further, with the package substrate and the method of manufacturing the same according to the preferred embodiment of the present invention, the damage of the insulation layer due the polishing process after the first through-via is formed may be prevented by the first metal layer formed on the upper portion of the insulation layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A package substrate comprising:
a base substrate;
insulation layers formed on upper and lower portions of the base substrate;
a first metal layer formed on an upper portion of the insulation layer;
a first through-via penetrating through the base substrate, the insulation layer, and the first metal layer and being made of an insulating material;
a seed layer formed on upper and lower portions and an inner wall of the first through-via;
a second metal layer formed on upper portions of the first metal layer and the seed layer; and
a second through-via formed in the seed layer formed at the inner wall of the first through-via and the second metal layer.

2. The package substrate as set forth in claim 1, wherein the base substrate is made of aluminum.

3. The package substrate as set forth in claim 1, wherein the insulation layer is an anodized film.

4. The package substrate as set forth in claim 1, wherein the insulating material is insulating plugging ink.

5. The package substrate as set forth in claim 1, wherein the seed layer is formed by a wet method or a dry method.

6. The package substrate as set forth in claim 1, wherein the second through-via is formed by at least one of plating, insulating plugging ink, and a conductive paste.

7. A method of manufacturing a package substrate, the method comprising:
preparing a base substrate;
forming insulation layers at upper and lower portions of the base substrate;
forming a first metal layer at an upper portion of the insulation layer;
forming a first through-hole penetrating through the base substrate, the insulation layer, and the first metal layer;
filling an inner portion of the through-hole with an insulating material to form a first through-via;
forming a second through-via penetrating through an inner portion of the first through-via;
forming a seed layer at upper and lower portions and an inner wall of the second through-hole;
forming a second metal layer at upper portions of the first metal layer and the seed layer; and
filling an inner portion of the second through-hole with a conductive material or insulating material to form a second through-via.

8. The method as set forth in claim 7, wherein the base substrate is made of aluminum.

9. The method as set forth in claim 7, wherein in the forming of the insulation layers, the base substrate is anodized.

10. The method as set forth in claim 7, wherein in the forming of the first through-via, the insulating material is insulating plugging ink.

11. The method as set forth in claim 7, wherein in the forming of the seed layer, the seed layer is formed by a wet method or a dry method.

12. The method as set forth in claim 7, wherein in the forming of the second through-via, the second through-via is formed by at least one of plating, insulating plugging ink, and a conductive paste.
